(19) United States
(12) Patent Application Publication
(10) Pub. No.: US 2007/0287226 A1
(43) Pub. Date: Dec. 13, 2007

(54) MANUFACTURING APPARATUS OF SEMICONDUCTOR DEVICE AND MANUFACTURING METHOD OF SEMICONDUCTOR DEVICE

(75) Inventors: Takuya Oga, Chiyoda-ku (JP); Mitsuhiro Kato, Chiyoda-ku (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/760,202

(22) Filed: Jun. 8, 2007

(30) Foreign Application Priority Data
Jun. 13, 2006 (JP) 2006-163703

(51) Int. Cl. H01L 21/00

(52) U.S. Cl. 438/108

(57) ABSTRACT

Detection of bumps' contact is enabled correctly, and the trouble of crushing a bump too much by an overshoot and connecting with an adjacent bump is abolished. The manufacturing apparatus of a semiconductor device and the manufacturing method of a semiconductor device which make it possible to perform stable flip chip bonding by an easy mechanism.

The manufacturing apparatus of the semiconductor device concerning the present invention has a stage where a substrate is arranged, a movable member formed made it possible to advance or retreat towards the stage, an elastic member formed in the movable member, a chip adsorption means which can adsorb the chip supported by the elastic member made it possible to advance or retreat towards a stage, a press means which can be pressed towards a stage about a chip adsorption means, a stopper which is formed in a movable member and can specify displacement of the direction close to a stage of a chip adsorption means by contacting a chip adsorption means from the stage side, a driving means which a movable member drives, and a control unit which controls operation of a driving means.

### CROSS-REFERENCE TO RELATED APPLICATION

The present application claims priority from Japanese patent application No. 2006-163703 filed on Jun. 13, 2006, the content of which is hereby incorporated by reference into this application.

1. Field of the Invention

The present invention relates to a manufacturing apparatus of a semiconductor device and a manufacturing method of a semiconductor device, and especially relates to a manufacturing apparatus of a semiconductor device and a manufacturing method of a semiconductor device by which the bump of a chip and the bump of a substrate are joined, and a semiconductor is manufactured.

2. Description of the Background Art

The bonding device which connects a chip and a substrate is known from the former (refer to following Patent Reference 1).

Generally a bonding device has the chip adsorption means which adsorbs a chip, the bonding stage where a substrate is arranged, a heating means to heat a bump, the driving means which makes a chip adsorption means move towards a bonding stage, and the load cell which measures the external force applied to a chip adsorption means.

In order to do bonding of a chip and the substrate using such a bonding device, where a chip is adsorbed, a chip adsorption means descends towards a bonding stage first.

Here, when the bump of a chip and the bump of a substrate contact, slight external force will be applied to a chip adsorption means, and when a load cell senses change of this external force, contact with a chip and a substrate will be detected. When a chip and a substrate contact, lowering of a chip adsorption means will stop and a heating means will drive. And when the temperature of a heating means turns into more than prescribed temperature, a chip adsorption means will descend slightly, will stop and release adsorption of a chip after that, and will do bonding of a chip and the substrate.

In such a conventional bonding device, since a chip adsorption means is guided by the linear guide, the frictional force by friction of a linear guide is also included in the external force which a load cell senses.

This frictional force changing, it is very difficult to do correctly sensing of the external force change generated when a chip and a substrate contact.

Then, the various proposals of the bonding device with which the device for doing sensing of the contact with a chip and a substrate correctly was made are made from the former (refer to Patent References 2 and 3).

For example, the bonding device described to Japanese Unexamined Patent Publication No. 2004-319599 is provided with the capillary which adsorbs a chip, and the support member which was arranged on the outside of a capillary, with which the clearance between capillaries was sealed, and which was supported with the flat spring.

The mechanisms accompanied by friction, such as linear bearing, are not included in the mechanism in which thrust is applied to a chip, and this bonding device can control very minute thrust with high precision.

[Patent Reference 1] Japanese Unexamined Patent Publication No. Hei 11-297749

[Patent Reference 2] Japanese Unexamined Patent Publication No. 2004-319599

[Patent Reference 3] Japanese Unexamined Patent Publication No. Hei 11-340273

### SUMMARY OF THE INVENTION

In the bonding device described to the above-mentioned Japanese Unexamined Patent Publication No. 2004-319599, lowering of the tool holding a flip chip is electrically controlled. Therefore, when contacting the electrically conductive bump of a flip chip, and a wiring substrate, heating them and adhering, it is difficult to control the height of a flip chip, forcing a flip chip on a wiring substrate by a predetermined bonding weight. For example, the adjoining bump was crushed too much by the overshoot, the circuit might be short-circuited and the joining defect of solder etc. might happen with the lack of load.

The present invention is made in view of the above-mentioned problem. Without including the mechanisms accompanied by friction, such as linear bearing, in the mechanism in which thrust is applied to a chip, minute thrust is made controllable with high precision, and detection of bumps' contact is enabled correctly. It aims at abolishing the trouble of crushing a bump too much by an overshoot and connecting with an adjacent bump, and performing stable flip chip bonding. It aims at making flip chip bonding possible by an easy mechanism.

A manufacturing apparatus of a semiconductor device concerning this invention comprises a stage where a substrate is arranged, a movable member formed so that it is possible to advance or retreat towards the stage, an elastic member formed in the movable member, a chip adsorption means which is supported by the elastic member so that it is possible to advance or retreat towards the stage, and which can adsorb a chip, a press means which can press the chip adsorption means towards the stage, a stopper which is formed in the movable member and which can specify displacement of a direction close to the stage of the chip adsorption means by contacting the chip adsorption means from the stage side, a driving means which drives the movable member, and a control unit which controls operation of the driving means.

A manufacturing method of a semiconductor device concerning this invention comprises the steps of making a chip stick to a chip adsorption means, moving the chip towards a substrate and contacting a bump of the chip and a bump of the substrate, pushing and pressing the chip adsorption means towards the substrate when contacting a bump of the chip, and a bump of the substrate, melting the bump by heating the bump where the bumps contact and the chip adsorption means has pushed and pressed towards the substrate, and stopping the chip adsorption means in contact with a stopper further after the chip adsorption means moves only prescribed distance towards the substrate after melting the bumps.

According to a manufacturing apparatus of a semiconductor device and a manufacturing method of a semiconductor device concerning the present invention, without including the mechanisms accompanied by friction, such as linear bearing in the mechanism in which thrust is applied to a chip, minute thrust is made controllable with high precision, and detection of bumps' contact is enabled correctly. The trouble of crushing a bump too much by an overshoot and connecting with an adjacent bump can be abolished, and stable flip chip bonding can be performed.

### BRIEF DESCRIPTION OF THE DRAWINGS

FIG. 1 is a side view of the bonding device concerning this embodiment;

FIG. 2 is a front view of the bonding device concerning this embodiment;

FIG. 3 is a plan view showing an example of a flat spring;

FIG. 4 is a plan view showing other examples of a flat spring;

FIG. 5 is a plan view showing the example of further others of a flat spring;

FIG. 6 is a partially sectional side view showing the first step of the manufacturing process of the semiconductor device concerning this embodiment;

FIG. 7 is a partially sectional side view showing the second step of the manufacturing process of the semiconductor device concerning this embodiment;

FIG. 8 is a partially sectional side view showing the third step of the manufacturing process of the semiconductor device concerning this embodiment;

FIG. 9 is a partially sectional side view showing the fourth step of the manufacturing process of the semiconductor device concerning this embodiment;

FIG. 10 is a cross-sectional view near a bump when the bump of a substrate and the bump of a substrate contact;

FIG. 11 is a cross-sectional view when the bump of a chip and the bump of a substrate melting and unifying and being set as a bump;

FIG. 12 is a flows-of-control picture when connecting the bump of a chip, and the bump of a substrate;

FIG. 13 is other flows-of-control picture when connecting the bump of a chip, and the bump of a substrate; and

FIG. 14 is a partially sectional side view showing the modification of the bonding device concerning this embodiment.

### DETAILED DESCRIPTION OF THE PREFERRED EMBODIMENTS

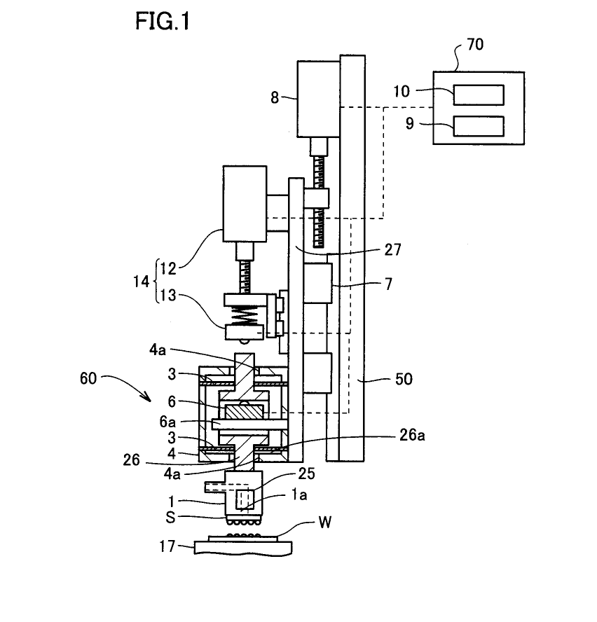

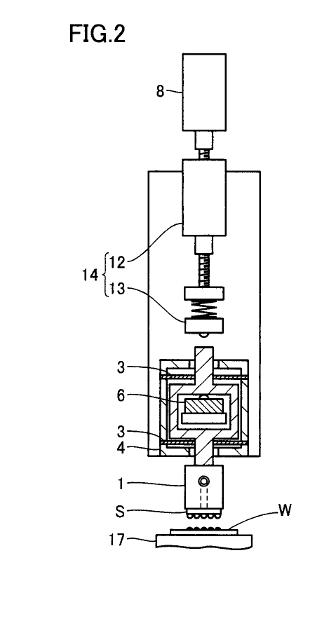

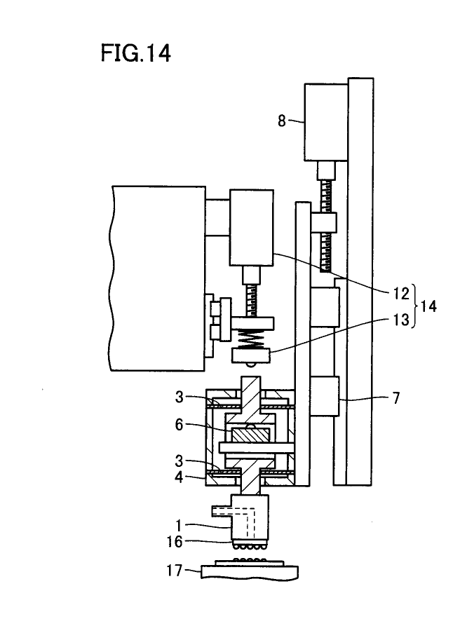

Bonding device 100 and a manufacturing method of a semiconductor device related to the present invention are explained using FIG. 14 from FIG. 1. FIG. 1 is a side view of bonding device 100 concerning this embodiment, and FIG. 2 is a front view of bonding device 100. Bonding device (manufacturing apparatus of a semiconductor device) 100 related to the present invention as shown in these FIG. 1 and FIG. 2 has bonding stage 17 where substrate W is arranged, movable member 27 formed in bonding head 50 via linear guide 7, bonding mechanism 60 formed in this movable member 27, force means 14, actuator 8 for a drive (first actuator), and control unit 70 which controls each operation.

Bonding stage 17 comprises rigid high materials, such as ceramics and stainless steel.

Via linear guide 7, movable member 27 is formed in bonding head 50, and is displaced by actuator 8 for a drive, and the advance or retreat of it is enabled towards bonding stage 17. Actuator 8 for a drive comprised a servo motor and a ball screw, changed the torque of the motor into the thrust with the ball screw, and has generated the thrust which slides movable member 27. It is good also as an air cylinder instead of actuator 8 for a drive, for example.

Bonding mechanism 60 is formed in the bonding stage 17 side among movable members 27. From bonding mechanism 60, force means 14 is the upper part and is formed in movable member 27.

Bonding mechanism 60 has chip adsorption means 1 which can adsorb chip S, support member 26 formed in this chip adsorption means 1, housing (case) 4 fixed to movable member 27, flat spring (elastic member) 3 formed in this housing 4, and load cell 6 for contact detection fixed to movable member 27.

The under surface which faces with bonding stage 17 among the front surfaces of chip adsorption means 1 is made into the bonding surface where chip S adsorbs. Heating means 25, such as a heater, are formed above this bonding surface.

Vacuum adsorption of chip adsorption means 1 is made possible by suction of air in chip S, and suction opening 1a is formed in the bonding surface.

Support member 26 is being fixed to the upper surface of this chip adsorption means 1, and at least a part of this support member 26 is located in housing 4.

Through hole 4a in which support member 26 arranged inside is inserted is formed in the upper and lower sides of housing 4. Support member 26 is supported with flat spring 3 within housing 4.

Flat spring 3 is formed in point symmetry centering on the central point (center-of-gravity point) of flat spring 3. This flat spring 3 is being fixed to housing 4 centering on the central point in the position of point symmetry.

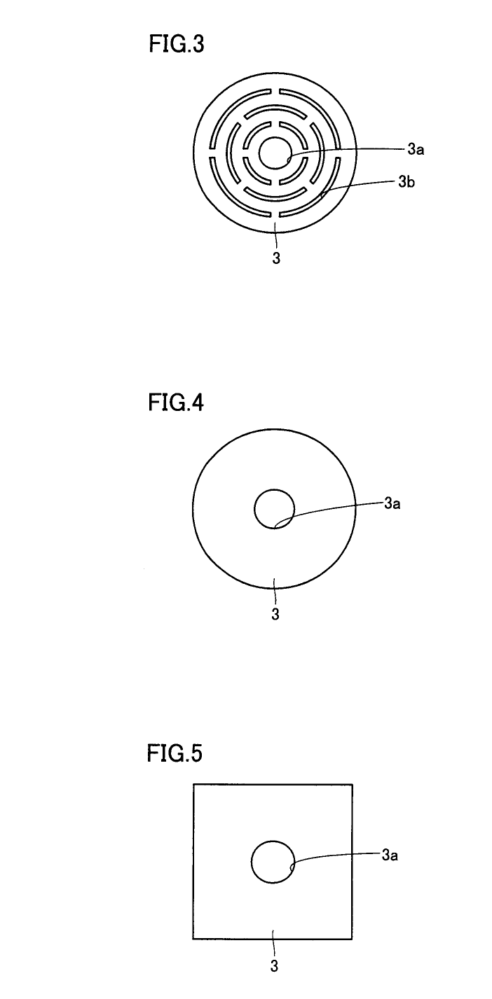

FIG. 3 is a plan view showing an example of flat spring 3, and as shown in this FIG. 3, it is formed in flat discoid. Through hole 3a in which support member 26 shown in FIG. 1 is inserted is formed in the central part comprising the central point of flat spring 3. A plurality of slits 3b which are formed focusing on this through hole 3a, and are extended and existed to a hoop direction are formed. Slit 3b is also arranged centering on the central point at point symmetry. Flat spring 3 formed in this way is arranged in housing 4 so that it may become parallel to the front surface of bonding stage 17.

When support member 26 which is shown in FIG. 1 and by which chip adsorption means 1 were formed successively is supported using such a flat spring 3, chip adsorption means 1 will be supported so that it can move towards bonding stage 17.

Since a plurality of slits 3b are formed especially, the deformation of flat spring 3 becomes large. Even if the stress applied to chip adsorption means 1 is minute, support member 26 and chip adsorption means 1 which are supported with flat spring 3 are displaced sensitively. Hereby when the bump of chip S which chip adsorption means 1 adsorbed, and the bump of substrate W arranged on bonding stage 17 contact, support member 26 and chip adsorption means 1 can be relatively displaced good to housing 4.

As shown in FIG. 1, a plurality of flat springs 3 are formed in housing 4. Each flat spring 3 of each other is spaced out in the advance-or-retreat direction of movable member 27.

Through hole 3a of each flat spring 3 shown in FIG. 3 is arranged on the vertical axis to the front surface of substrate W shown in FIG. 1. The axis line of support member 26 is arranged so that it may become vertical to substrate W. It arranges so that the front surface of chip S which the under surface of chip adsorption means 1 adsorbs, and the front surface of substrate W may become parallel mutually by this. It can suppress that support member 26 inclines to the advance-or-retreat direction (it is a vertical direction to the front surface of substrate W) of support member 26 by separating a gap in the advance-or-retreat direction of support member 26, and supporting support member 26 with flat spring 3.

Hereby, it can suppress that chip S with which chip adsorption means 1 connected to support member 26 was equipped inclines to substrate W. Chip S can be made to be able to approach towards substrate W, maintaining the state where the upper surface of substrate W and the under surface of chip S were made parallel.

FIG. 4 is a plan view showing other examples of flat spring 3, and as shown in this FIG. 4, it may form flat spring 3 disc-like. FIG. 5 is a plan view showing the example of further others of flat spring 3, and as shown in this FIG. 5, it is good also as a square shape.

Namely, flat spring 3 should just be made into point symmetry form making the central point the center. Form, such as polygonal shape, circular form, and elliptical, is employable.

Support member 26 is provided with containing section 26a which has an opening on the side surface at the side of movable member 27 of support member 26 and which consists of a recess or a through hole in FIG. 1.

Load cell 6 for contact detection fixed to movable member 27 is stored by this containing section 26a. Load cell 6 for contact detection is being fixed to the other end side of holddown member 6a by which one end was fixed to movable member 27. This load cell 6 for contact detection is made measurable in the contact force generated between support members 26, and it is arranged so that support member 26 can be supported from the bonding stage 17 side.

The width of the direction where support member 26 moves of containing section 26a is formed more greatly than the width of load cell 6 for contact detection.

For this reason, when external force is applied to chip adsorption means 1, flat spring 3 will do elastic deformation and will do relative displacement of the support member 26 to movable member 27. Since load cell 6 for contact detection is being fixed to movable member 27 within containing section 26a at this time, it is relatively displaced to support member 26.

Force means 14 is provided with actuator 12 for press which pushes and presses the top end of support member 26, and load cell 13 for thrust detection which is formed in the bottom end of actuator 12 for press, and measures the thrust applied to support member 26. Actuator 12 for press is formed in the same as the above-mentioned actuator 8 for a drive, and not only the structure of a servo motor and a ball screw but a linear motor is sufficient as actuator 12 for press.

Control unit 70 is provided with memory means 10 by which each parameter was stored, and control means 9 which controls the drive of actuator 12 for press, actuator 8 for a drive, etc.

How to do bonding of a chip and the substrate and to manufacture a semiconductor device is explained using bonding device 100 formed as mentioned above.

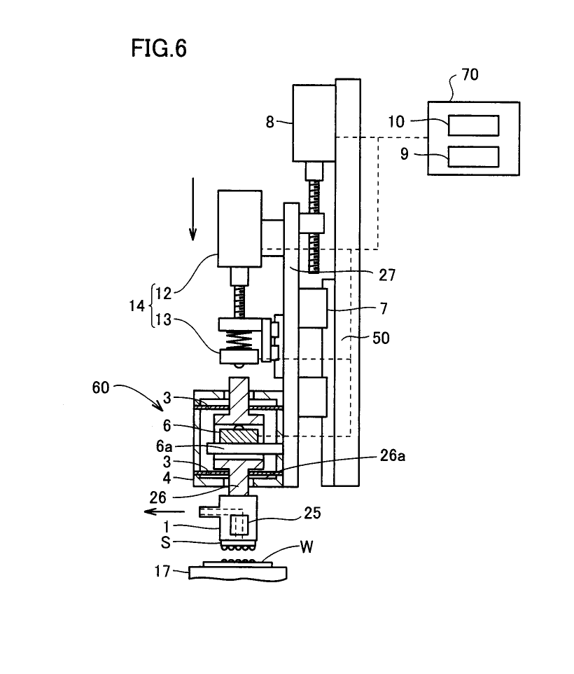

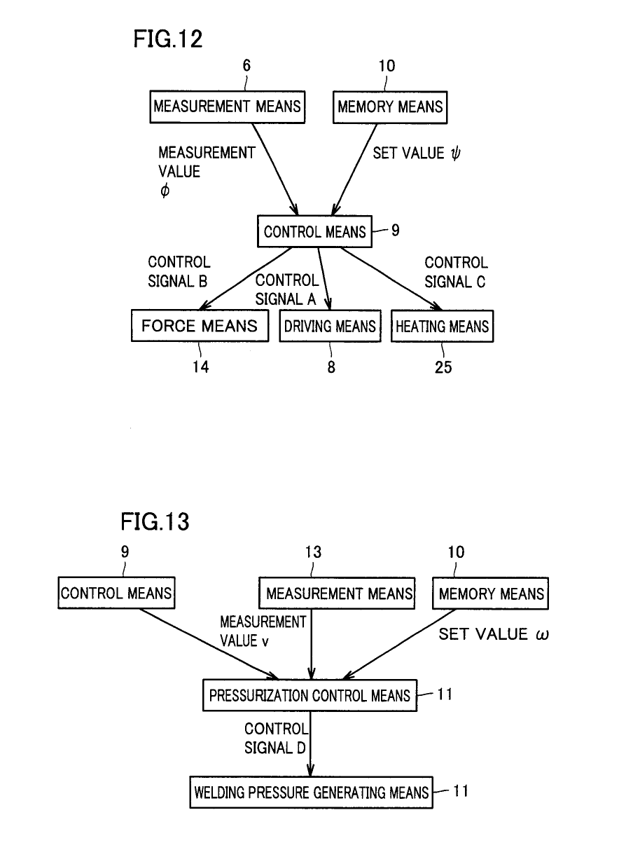

FIG. 6 is a partially sectional side view showing the first step of the manufacturing process of the semiconductor device concerning this embodiment. FIG. 12 shows the flows of control when connecting the bump of chip S, and the bump of substrate W.

As shown in FIG. 6, chip adsorption means 1 adsorbs chip S first. And chip S is transported on bonding stage 17. According to the alignment mechanism which is not illustrated, horizontal alignment of chip S and substrate W is done, and the bump of substrate W and the bump of chip S are made to correspond in an up-and-down direction.

On this occasion, load cell 6 for contact detection touches the internal surface of containing section 26a. Load cell 6 for contact detection is pushing and pressing support member 26 towards the upper part from the bonding stage 17 side. That is, support member 26 and chip adsorption means 1 are supported by flat spring 3 and load cell 6 for contact detection. The weight of support member 26 and chip adsorption means 1 balances with the thrust from load cell 6 for contact detection, and the thrust from flat spring 3.

Thus, the mechanism which supports support member 26 and chip adsorption means 1 is a thing like linear guide 7 which does not include the mechanism in which friction generates.

And after the balance of the force of support member 26, flat spring 3, and load cell 6 for contact detection has balanced as mentioned above, when slight external force is applied to chip adsorption means 1 from the outside, the contact force between load cell 6 for contact detection and support member 26 will be changed. Especially the rigidity of load cell 6 for contact detection and support member 26 is larger than flat spring 3, and the elastic deformation of load cell 6 for contact detection and support member 26 is small. Therefore, load cell 6 for contact detection can detect change of the external force applied to support member 26 with high precision.

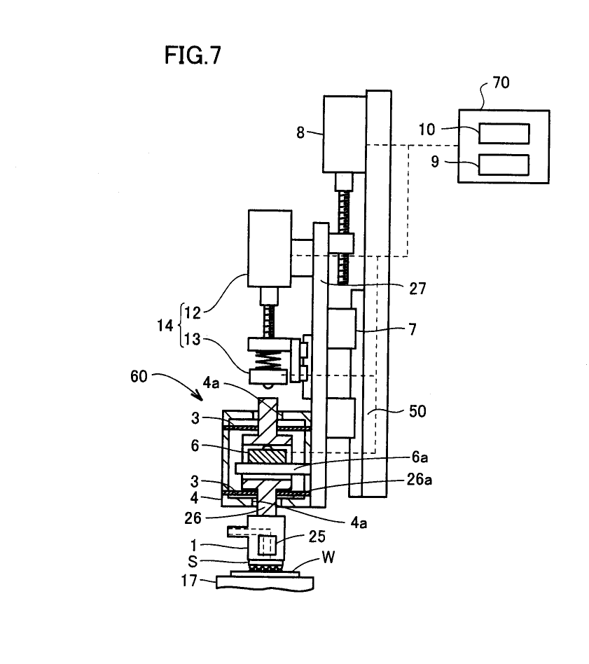

FIG. 7 is a partially sectional side view showing the second step of the manufacturing method of the semiconductor device concerning this embodiment. As shown in this FIG. 7, after the stress state of support member 26, flat spring 3, and load cell 6 for contact detection has balanced, control means 9 drives actuator 8 for a drive, and descends movable member 27 towards bonding stage 17. The alignment of substrate W and chip S is completed and let the position of movable member 27 just before movable member 27 is displaced below be a reference point of movable member 27.

And when the bump of chip S and the bump of substrate W contact, chip adsorption means 1 will be supported by the bump of substrate W. It changes so that the stress generated between load cell 6 for contact detection and support member 26 may become small. As mentioned above, since load cell 6 for contact detection can detect stress change with sufficient accuracy, it can judge that the bump of substrate W and the bump of chip S contacted.

Concretely, in FIG. 12, control means 9 descends movable member 27 until measurement value φ which is detected by load cell 6 for contact detection, and which is generated between load cell 6 for contact detection and support member 26 reaches set value ψ stored in memory means 10 shown in FIG. 1.

And it memorizes for memory means 10 by making the position of movable member 27 into a point of contact when measurement value φ turns into set value ψ.

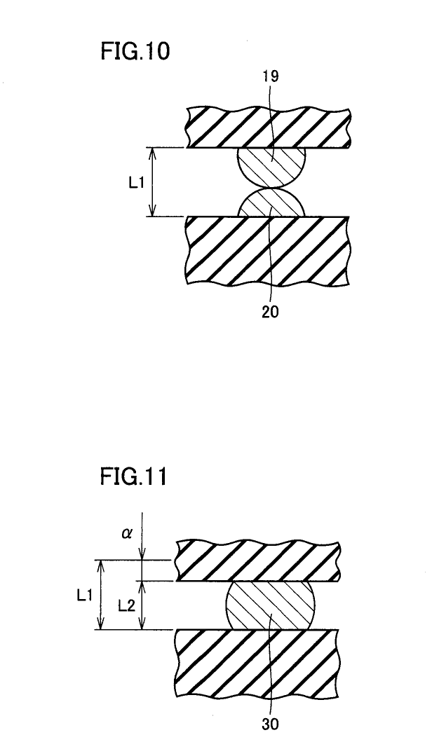

FIG. 10 is a cross-sectional view of the bump 19 and 20 neighborhood when bump 19 of chip S and bump 20 of substrate W contact. In this FIG. 10, bumps 19 and 20 are formed from hemispherical solder. And the front surface of substrate W and the front surface of chip S are spaced out distance L1.

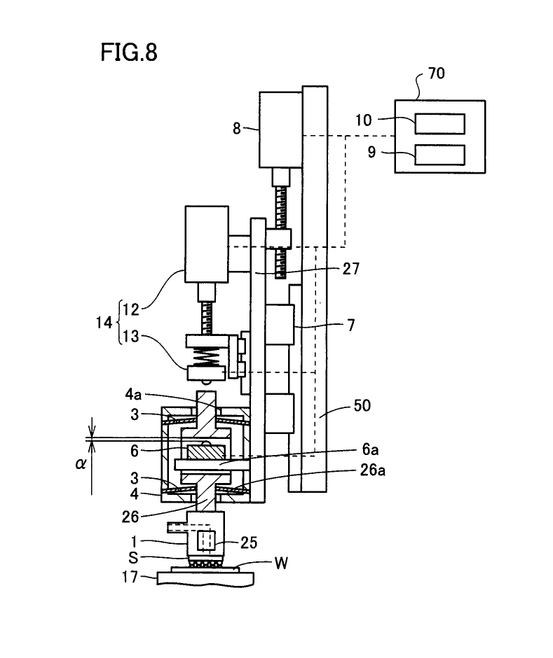

FIG. 8 is a partially sectional side view showing the third step of the manufacturing process of the semiconductor device concerning this embodiment. In this FIG. 8 and FIG. 12, with control signal A from control means 9, actuator 8 for a drive is made to drive further, and movable member 27 descends only prescribed distance α towards bonding stage 17.

Thus, when movable member 27 is displaced towards a lower part in the state where the bump of substrate W and the bump of chip S are in contact, while load cell 6 for contact detection fixed to movable member 27 will also be displaced below, chip adsorption means 1 and support member 26 are maintained in the above-mentioned contact position.

For this reason, load cell 6 for contact detection which was in contact with the internal surface of containing section 26a of support member 26 spaces out only prescribed distance α from the internal surface of containing section 26a.

Since housing 4 is relatively displaced below to support member 26 and chip adsorption means 1, to support member 26, flat spring 3 deforms so that it may push and press towards bonding stage 17, and pushes and presses chip S towards substrate W slightly.

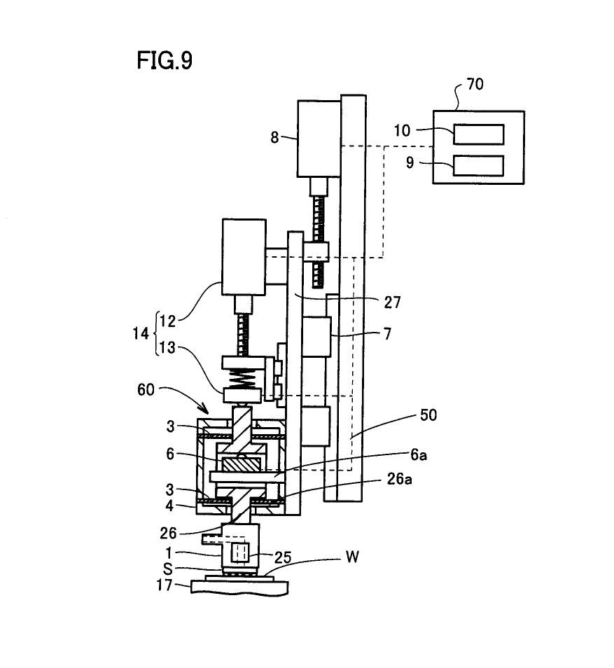

FIG. 9 is a partially sectional side view showing the fourth step of the manufacturing process of the semiconductor device concerning this embodiment. In this FIG. 9 and FIG. 12, force means 14 is driven with control signal B from control means 9.

Hereby, actuator 12 for press drives and load cell 13 for thrust detection descends towards bonding stage 17. And load cell 13 for thrust detection pushes and presses the upper end surface of support member 26, and makes bump 19 and bump 20 push and press.

And control means 9 controls the actuator for press so that measured value v which load cell 13 for thrust detection detects may turn into set value ω stored in memory means 10 and suppresses that excessive stress occurs between bumps 19 and 20.

Thus, after pushing and pressing bump 19 and bump 20, heating means 25 drives with control signal C from control means 9. In FIG. 9, the heat from heating means 25 heat-conducts the inside of chip adsorption means 1, and is conducted to chip S from a bonding surface, and bumps 19 and 20 of chip S are heated. As for heating means 25, temperature is controlled by control signal C from control means 9, and the generation of too much heat is suppressed.

FIG. 11 is a cross-sectional view when bump 20 of substrate W and bump 19 of chip S melting and unifying, and being set as bump 30.

As shown in this FIG. 11 and FIG. 10, by heating means 25, bump 20 and bump 19 are heated and melt. Since support member 26 is pushed and pressed towards bonding stage 17 in FIG. 9 when bump 20 and bump 19 melt and they become liquid, support member 26 and chip adsorption means 1 are displaced towards bonding stage 17.

And chip adsorption means 1 and support member 26 are displaced to the bonding stage 17 side, and chip S is pushed in only prescribed distance α towards substrate W. Then, the internal surface of containing section 26a and the load cell for contact detection contact, the displacement to the lower part of support member 26 is specified, and lowering of chip adsorption means 1 stops. That is, after bumps 19 and 20 melt, load cell 6 for contact detection is functioning as a stopper which specifies the displacement in which chip adsorption means 1 is displaced towards bonding stage 17.

Thus, when chip adsorption means 1 is displaced towards bonding stage 17 after bumps 19 and 20 have melted, bump 19 and bump 20 becomes bump 30 of one, and chip S is connected with substrate W.

Since the stress generated between bumps 19 and 20 will decrease when bump 20 of substrate W and bump 19 of chip S melt, the contact force generated between support member 26 and load cell 6 for contact detection increases. When load cell 6 for contact force detection detects change of this contact force, it is detectable that bumps 19 and 20 dissolved.

Thus, when the measured value of load cell 6 for contact force detection is changed, control means 9 can stop the drive of actuator 12 for press, and can suppress too much pressurization.

Thus, it can suppress that bump 30 formed is crushed too much and adjacent bumps connect, without the falling position of chip S overshooting, since chip adsorption means 1 can be stopped in mechanical. Hereby, good bonding can be performed.

Though insulating films, such as an oxide film, were formed in bumps' 19 and 20 front surface since it was made to dissolve after pushing bumps 19 and 20, it can destroy, when pushing bumps 19 and 20, and good electric connection can be performed.

Moreover, the distance of chip S and substrate W can be correctly set as predetermined distance L2, and it can suppress that variation occurs in each semiconductor device manufactured.

Force means 14 may consist of air cylinders. In that case, in FIG. 13, an air cylinder is sufficient as actuator 12 for press (welding pressure generating means). Pressurization control means 11 which controls the thrust of actuator 12 for press by control signal B from control means 9 should just be a precision generator regulator. Load cell 13 for thrust detection in particular shown in FIG. 1 does not have the need.

FIG. 14 is a partially sectional side view showing the modification of bonding device 100 concerning this embodiment. As shown in this FIG. 14, force means 14 does not need to adhere to bonding head 50, and as shown in FIG. 14, it may be supported by a different structured division from bonding head 50.

The embodiment of the invention was explained as mentioned above. However, with all the points, the embodiment disclosed this time is exemplification and should be considered not to be restrictive. The range of the present invention is shown by the claim. It is meant that a claim, and all the change in a meaning and within the limits equivalent to the claim are included.

The present invention relates to the manufacturing apparatus of a semiconductor device and the manufacturing method of a semiconductor device, and it is especially suitable to the manufacturing apparatus of a semiconductor device and the manufacturing method of a semiconductor device which manufacture a semiconductor device by joining the bump of a chip, and the bump of a substrate.

What is claimed is:

1. A manufacturing apparatus of a semiconductor device, comprising:
a stage where a substrate is arranged;
a movable member formed so that it is possible to advance or retreat towards the stage;
an elastic member formed in the movable member;
a chip adsorption means which is supported by the elastic member so that it is possible to advance or retreat towards the stage, and which can adsorb a chip;
a press means which can press the chip adsorption means towards the stage;
a stopper which is formed in the movable member and which can specify displacement of a direction close to the stage of the chip adsorption means by contacting the chip adsorption means from the stage side;
a driving means which drives the movable member; and
a control unit which controls operation of the driving means.

2. A manufacturing apparatus of a semiconductor device according to claim 1, wherein
the stopper is a load cell for contact detection measurable in a contact force generated between the chip adsorption means.

3. A manufacturing apparatus of a semiconductor device according to claim 1, wherein
the press means includes a thrust generating means which generates thrust which pushes and presses the chip adsorption means, and a load cell for thrust detection measurable in a contact force generated between the chip adsorption means.

4. A manufacturing apparatus of a semiconductor device according to claim 1, wherein
a chip adsorption means includes a heating mechanism.

5. A manufacturing apparatus of a semiconductor device according to claim 1, wherein
the elastic member is a flat spring which can support a chip adsorption means, as the chip is perpendicularly moved to the substrate.

6. A manufacturing method of a semiconductor device, comprising the steps of:
making a chip stick to a chip adsorption means;
moving the chip towards a substrate and contacting a bump of the chip and a bump of the substrate;
pushing and pressing the chip adsorption means towards the substrate when contacting a bump of the chip, and a bump of the substrate;
melting the bump by heating the bump where the bumps contact and the chip adsorption means has pushed and pressed towards the substrate; and
stopping the chip adsorption means in contact with a stopper further after the chip adsorption means moves only prescribed distance towards the substrate after melting the bumps.

7. A manufacturing method of a semiconductor device according to claim 6, comprising the steps of:
moving the chip adsorption means which adsorbed the chip towards a bonding stage where the substrate has been arranged where the stopper which is relatively formed movable to the chip adsorption means and which is made measurable in a contact force generated between the chip adsorption means is contacted to the chip adsorption means; and
detecting change of contact force generated between the chip adsorption means and the stopper, and detecting contact with a bump of the chip, and a bump of the substrate.
